(19) United States
(12) Patent Application Publication
(10) Pub. No.: US 2011/0277841 A1
(43) Pub. Date: Nov. 17, 2011

(54) THIOCYANATE-FREE RU(II) SENSITIZERS AND DYE-SENSITIZED SOLAR CELLS

(76) Inventors: Yun CHI, Hsinchu (TW); Kellen CHEN, Hsinchu (TW); Hui-Chu HSU, Hsinchu (TW); Kuan-Lin WU, Hsinchu (TW)

(21) Appl. No.: 12/895,276

(22) Filed: Sep. 30, 2010

(30) Foreign Application Priority Data
May 14, 2010 (TW) 099115401

(51) Int. Cl. H01L 51/46; C07F 15/00

(52) U.S. Cl. 136/263; 546/2

(57) ABSTRACT

Photosensitizers having a formula of RuL₁L₂L₃ are provided, wherein Ru is ruthenium; L₁, L₂ and L₃ represent heterocyclic bidentate ligands. L₁ has a chemical formula represented by formula (b), L₂ has a chemical formula represented by formulae (b), (c), (d) or (e), and L₃ a chemical formula represented by formulae (c), (d) or (e). Each of R1 to R18 is a member independently selected from the group consisted of hydrogen, halogen, aryl group, alkenyl group, C1-C20 alkyl group, cycloalkyl group, alkynyl group, CN, CF₃, alkylamino, amino, alkoxy, heteroaryl, halogen substituted aryl group, halogen substituted aromatic group, haloalkyl substituted aryl group, haloalkyl substituted aromatic group and aryl substituted C1-C20 alkyl group. The above-mentioned photosensitizers are suitable to serve as sensitizers for fabrication of high efficiency dye-sensitized solar cells.

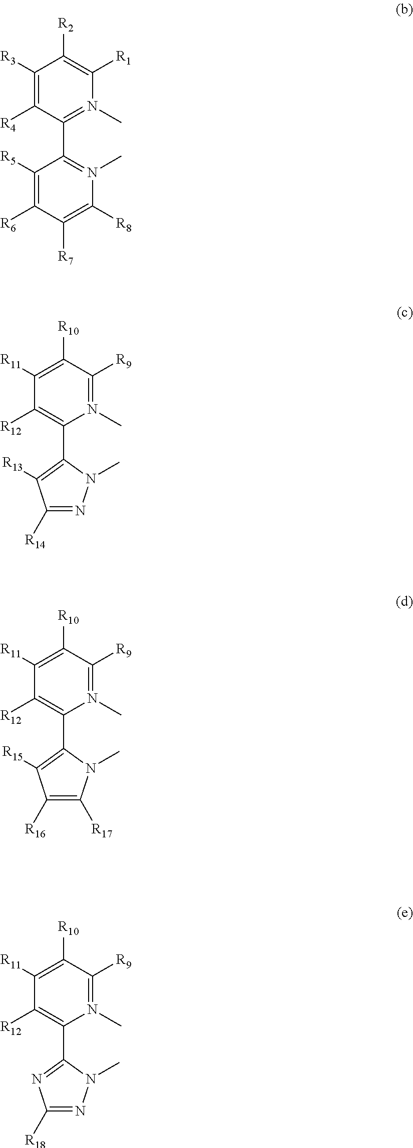

### BACKGROUND OF THE INVENTION

1. Field of the Invention

The present invention relates to sensitizers and dye-sensitized solar cells, particularly to thiocyanate-free Ru(II) sensitizers and dye-sensitized solar cells with improved photoelectric conversion efficiency.

2. Description of the Prior Art

Petrochemical fuel is a nonrenewable energy source and might possibly run out very soon. In addition, burning petrochemical fuel results in excessive CO₂ exhausts which not only pollute the atmosphere, but also become one of the primary causes of global warming. Therefore, searching for alternative energy supplies to reduce reliance on petrochemical fuels is a subject of great urgency.

During the development of green energy, it is found that solar energy is the cleanest, most abundant and requires neither mining nor refinement. Solar energy, therefore, becomes the most promising technology among the current development and search for new energy. The manufacturing process of a dye-sensitized solar cell (DSSC) is simple and the associated fabrication cost is also significantly lower than that of a silicon-based solar cell of prior arts. Therefore, DSSC has been regarded as one of the most notable solar cell technologies following silicon-based solar cells.

Because the intrinsic properties of photosensitizers directly affect the photoelectric conversion efficiency of a DSSC, the photosensitizers therefore becomes one of key issues while conducting research on DSSCs.

A N719 dye is a photosensitizer commonly used at present, which comprises the structure shown in Formula (I). However, the absorption spectrum of N719 dye is not well matched to the solar spectrum, which makes N3 dye to respond sluggishly to solar irradiations, particularly for solar radiation with wavelengths greater than 600 nm, and cannot effectively use the solar energy in this region. In addition, the conventional N719 dye has weaker coordination bonding interaction associated with the NCS⁻ (thiocyanate) ligands. Therefore, replacing NCS⁻ ligands with other aromatic chelating anions or chromophores would allow significant increase of efficiency and life-expectancy of DSSCs.

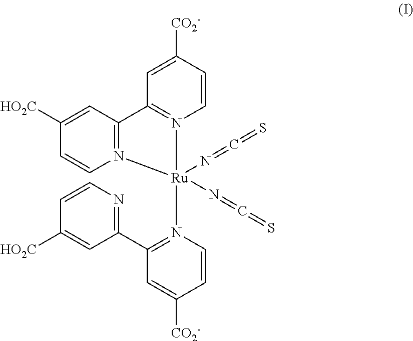

To sum up the foregoing descriptions, the photoelectric conversion efficiency of a DSSC is directly dependent to the inherent property of photosensitizer; therefore, developing photosensitizers with decent photoelectric conversion efficiency is an important goal to be achieved.

### SUMMARY OF THE INVENTION

The present invention is directed to the design and preparation of photosensitizers having heterocyclic bidentate ligands in substitution of thiocyanates for better photoelectric conversion efficiency.

According to one embodiment of the present invention, a photosensitizer comprises a chemical formula represented by formula (a):

RuL₁L₂L₃ (a)

wherein Ru is ruthenium, and L₁, L₂ and L₃ represent heterocyclic bidentate ligands. L₁ has a chemical formula represented by formula (b). L₂ has a chemical formula represented by formulae (b), (c), (d) or (e). L₃ has a chemical formula represented by formulae (c), (d) or (e).

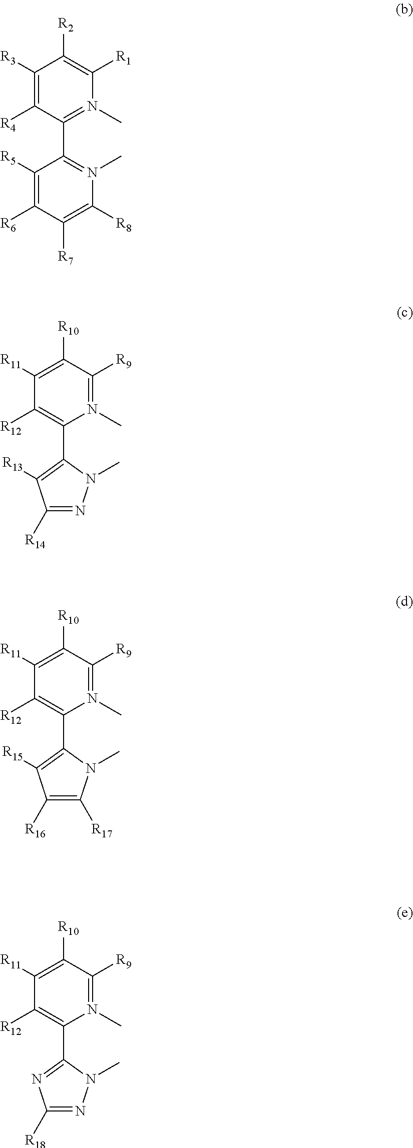

Each of R1 to R18 is a member independently selected from the group consisted of hydrogen, halogen, aryl group, alkenyl group, C1-C20 alkyl group, cycloalkyl group, alkynyl group, CN, CF₃, alkylamino, amino, alkoxy, heteroaryl, halogen substituted aryl group, haloalkyl substituted aryl group, haloalkyl substituted aromatic group and aryl substituted C1-C20 alkyl group.

The present invention is also directed to the fabrication of dye-sensitized solar cells, which have better photoelectric conversion efficiency and improved device efficiency and longer life-expectancy for DSSCs.

According to another embodiment, a DSSC comprises a first electrode (photoanode), a second electrode (cathode) and an electrolyte. The first electrode comprises a transparent conductive substrate and a porous membrane, wherein the porous membrane, disposed on a surface of the transparent conductive substrate, comprises a semiconductor material and is loaded with the aforementioned photosensitizers. The electrolyte is disposed between the porous membrane and the second electrode.

Other advantages of the present invention will become apparent from the following descriptions taken in conjunction with the accompanying drawings wherein certain embodiments of the present invention are set forth by way of illustration and examples.

### BRIEF DESCRIPTION OF THE DRAWINGS

The foregoing aspects and many of the accompanying advantages of this invention will become more readily appreciated as the same becomes better understood by reference to the following detailed descriptions, when taken in conjunction with the accompanying drawings, wherein:

FIG. 1 is a diagram illustrating absorption spectra of photosensitizers according to one preferred embodiment of the present invention and N719; and

FIG. 2 is a schematic diagram illustrating the structure of a dye-sensitized solar cell according to one embodiment of the present invention.

### DESCRIPTION OF THE PREFERRED EMBODIMENT

Photosensitizers according to one preferred embodiment of the present invention comprise a chemical formula represented by formula (a):

RuL₁L₂L₃ (a)

wherein Ru is ruthenium; L₁, L₂ and L₃ represent heterocyclic bidentate ligands; L₁ has a chemical formula represented by formula (b); L₂ has a chemical formula represented by formulae (b), (c), (d) or (e); and L₃ has a chemical formula represented by formulae (c), (d) or (e).

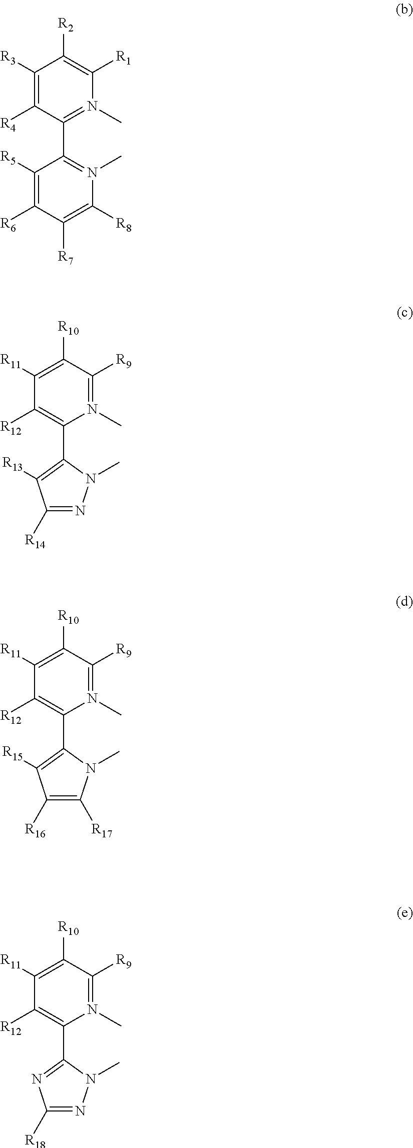

Each of R1 to R18 is a member independently selected from the group consisted of hydrogen, halogen, aryl group, alkenyl group, C1-C20 alkyl group, cycloalkyl group, alkynyl group, CN, CF₃, alkylamino, amino, alkoxy, heteroaryl, halogen substituted aryl group, haloalkyl substituted aryl group, haloalkyl substituted aromatic group and aryl substituted C1-C20 alkyl group.

For example, the photosensitizers of the present invention include core coordination structures having but not limited to formulae (f) to (1).

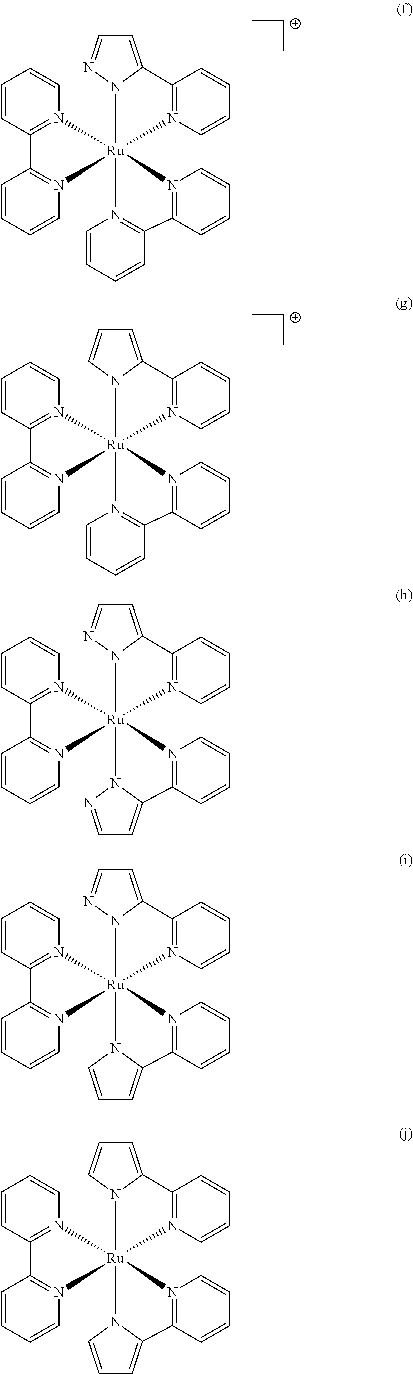

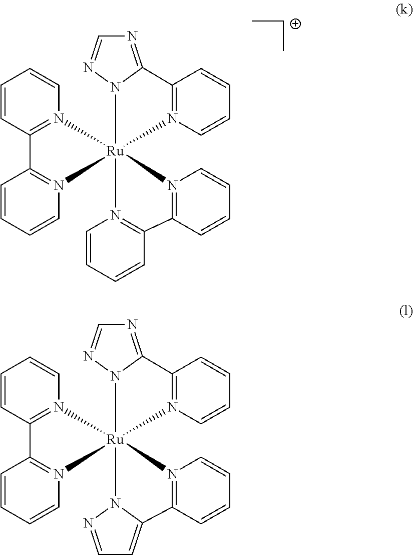

In one embodiment, each of R3 and R6 in formula (b) may be independently selected from the group consisted of carboxyl group and carboxyvinyl group, and each of R14 in formula (c), R15 and R17 in formula (d) and R18 in formula (e) may be independently CF₃. Preferably, the present invention includes compounds represented by formulae (m) to (s).

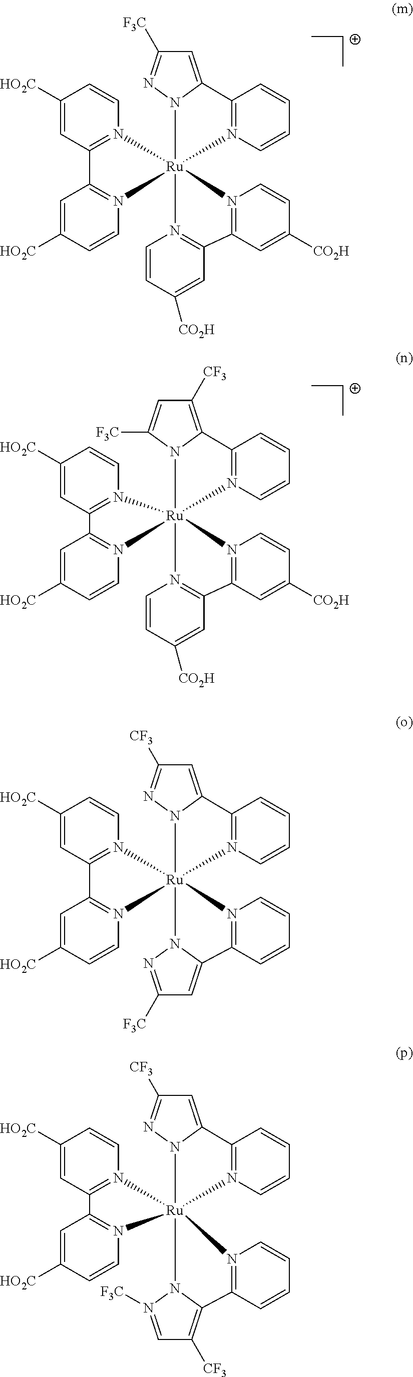

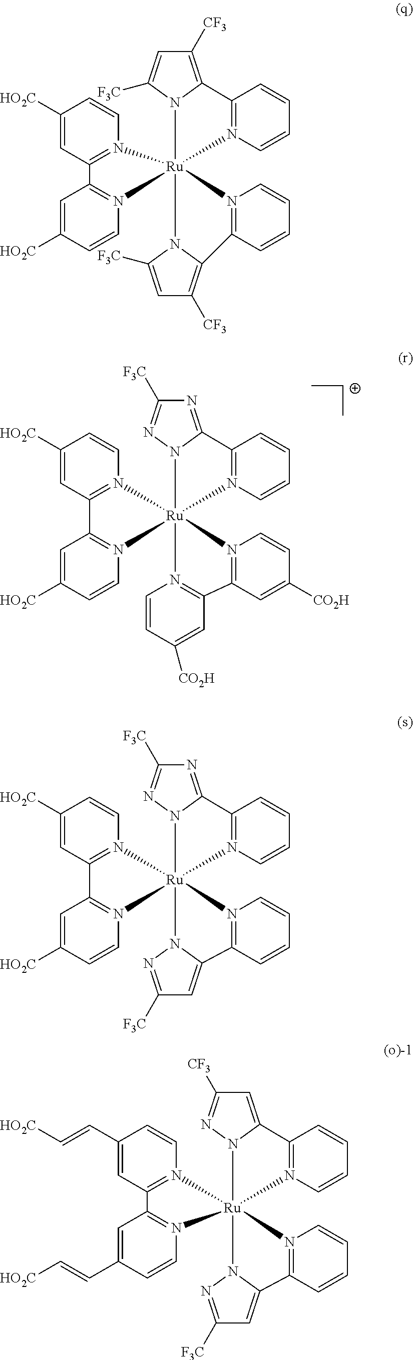

In one embodiment, each of R11, R13 in formula (c) and R11, R16 in formula (d) is a member independently selected from the group consisted of aryl group, heteroaryl group, halogen substituted aryl group, haloalkyl substituted aryl group, haloalkyl substituted aromatic group and aryl substituted C1-C20 alkyl group. In one preferred embodiment, each of R11, R13 in formula (c) and R11, R16 in formula (d) is a member independently selected from thiophene, 5-(thiophen-2-yl)thiophene, thiophene-substituted C1-C20 alkyl group, 5-(thiophen-2-yl)thiophene-substituted C1-C20 alkyl group, 1-tert-butyl-4-[(1E)-prop-1-en-1-yl]benzene and N,N-diphenylaniline. For example, each of R11, R13 in formula (c) and R11, R16 in formula (d) may be represented by following chemical formulae, wherein R′ is C1-C20 alkyl group or C1-C20 cycloalkyl group.

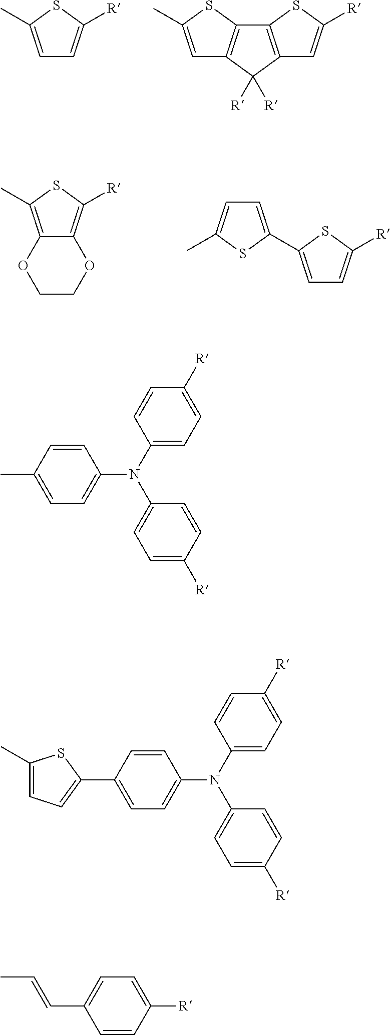

### Example 1

In one preferred embodiment, the photosensitizer of the present invention is represented as formula (t). Here, the photosensitizer TFRS-1 has R═H; the photosensitizer TFRS-2 has R=5-hexylthiophene; and the photosensitizer TFRS-3 has R=5-hexyl[2,2′]bithiophene.

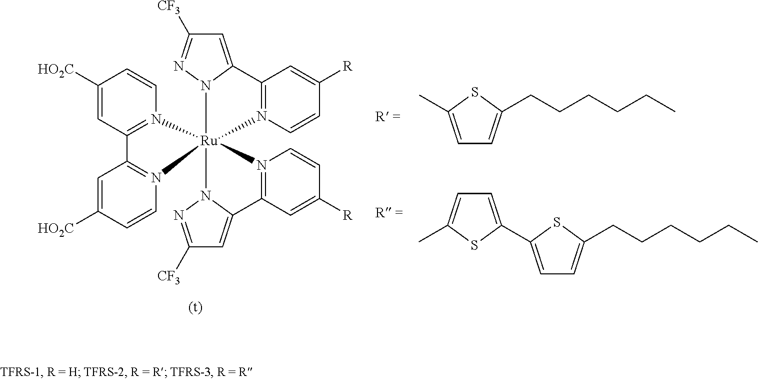

TFRS-1, TFRS-2 and TFRS-3 may be synthesized with the equation listed below.

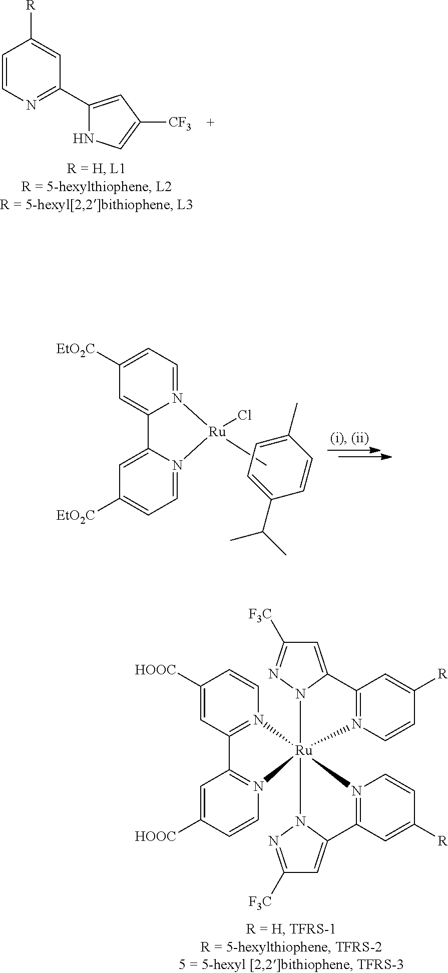

To be specific, TFRS-1 was prepared by direct treatment of 2-(3-(Trifluoromethyl)-1H-pyrazol-5-yl)pyridine (45 mg, 0.21 mmol) and [Ru(4,4′-bis(ethoxycarbonyl)-2,2′-bipyridine)(p-cymene)C1]C1 (60 mg, 0.10 mmol), which were dissolved in 2-methoxyethanol (20 mL), and the reaction mixture was heated to 130° C. under stirring for 12 h. After evaporating the solvent, the residue was extracted with dichloromethane and washed with deionized water three times (3×25 mL). Evaporation of solvent then produced the crude product, which was then purified by silica gel column chromatography (CH₂Cl₂/EtOAc=5:1). Finally, the resulting solid was dissolved in a mixture of acetone (5 mL) and 1M sodium hydroxide (5 mL). The solution was heated to 100° C. under N2 for 24 h. After completing the hydrolysis, the solvent was removed again and solid was dissolved in basified H₂O solution (10 mL) and was titrated with 2 M HCl to pH 3 to afford a brown precipitate. This brown product was then taken into a minimum amount of methanol and purified on Sephadex LH-20 column using methanol as the eluent. The main band was collected by evaporation of methanol solvent to dryness.

Synthesis of TFRS-2 and TFRS-3: A similar procedure was conducted as described for TFRS-1, starting from 5-hexylthiophene pyridyl pyrazole and 5-hexyl[2,2′]bithiophene pyridyl pyrazole. All experimental procedures are identical and hence were omitted for clarity. TFRS-1 was isolated in 32.4% yield, while TFRS-2 and TFRS-3 were isolated in 27% and 35% of yields, respectively

The spectral data of TFRS-1: MS (FAB, ¹⁰²Ru): m/z 771 (M+1)⁺. ¹H NMR (400 MHz, d₆-DMSO, 298 K): δ 8.95 (s, 1H), 8.14 (d, J=6.0 Hz, 1H), 7.99 (d, J=8.0 Hz, 1H), 7.83 (t, J=8.0 Hz, 1H), 7.78 (d, J=5.2 Hz, 1H), 7.28 (s, 1H), 7.21 (t, J=6.0 Hz, 1H), 7.64 (d, J=5.2 Hz, 1H). Anal. Calcd for C₃₀H₁₈F₆N₈O₄Ru.4H₂O: C, 42.81; N, 13.31; H, 3.11. Found: C, 43.08; N, 12.96; H, 3.18.

The spectral data of TFRS-2: MS (FAB, ¹⁰²Ru): m/z 1103 (M+1)⁺. ¹H NMR (d₆-DMSO, 400 MHz): δ 8.96 (s, 2H), 8.27 (d, J=6.4 Hz, 2H), 8.22 (s, 2H), 7.79 (d, J=6 Hz, 2H), 7.74 (d, J=3.2 Hz, 2H), 7.45 (s, 2H), 7.42 (d, J=6 Hz, 2H), 7.05 (d, J=6 Hz, 2H), 6.96 (d, J=3.2 Hz, 2H), 2.82 (t, J=7.2 Hz, 4H), 1.61˜0.83 (m, 22H). Anal. Calcd for C₅₀H₄₆F₆N₈O₄RuS₂.H₂O: C, 53.61; N, 10.00; H, 4.32. Found: C, 53.93; N, 9.79; H, 4.36.

The spectral data of TFRS-3: MS (FAB, ¹⁰²Ru): m/z 1267 (M+1)⁺. ¹H NMR (d₆-DMSO, 400 MHz): δ 8.94 (s, 2H), 8.28-8.26 (m, 4H), 7.86 (d, J=3.6 Hz, 2H), 7.79 (d, J=6 Hz, 2H), 7.48-7.52 (m, 4H), 7.34 (d, J=3.6 Hz, 2H), 7.20 (d, J=3.6 Hz, 2H), 7.07 (d, J=6.4 Hz, 2H), 6.83 (d, J=3.6 Hz, 2H), 2.76 (t, J=7.6 Hz, 4H), 1.61-1.24 (m, 16H), 0.83 (t, J=7.2 Hz, 6H). Anal. Calcd for C₅₈H₅₀F₆N₈O₄RuS₄.4H₂O: C, 52.05; N, 8.37; H, 4.37. Found: C, 52.28; N, 8.28; H, 4.28.

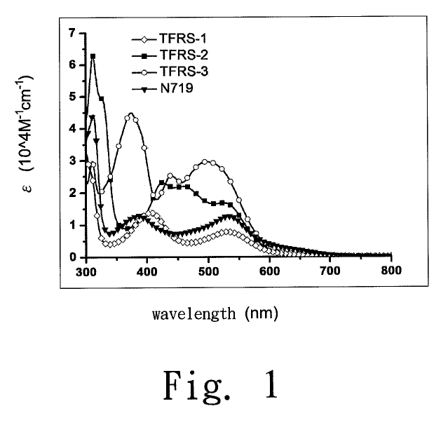

Refer to FIG. 1, which illustrates absorption spectra of photosensitizers having the formula (t) and N719. Compared to N719, photosensitizers TFRS-2 and TFRS-3 have better absorption coefficients for most of visible spectral regions, as illustrated in FIG. 1.

### Example 2

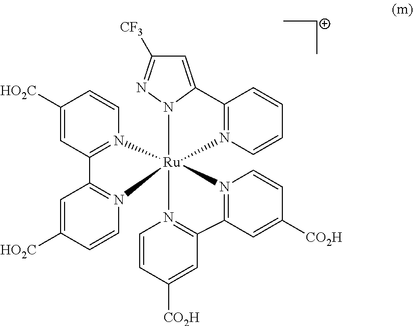

Compound (m) was prepared by treatment of dichloro(p-cymene)ruthenium (II) (75 mg, 0.117 mmol) with 2-(3-(trifluoromethyl)-1H-pyrazol-5-yl)pyridine (49 mg, 0.230 mmol) in refluxing DMF at 140° C. for 3 hours, followed by addition of 4,4′-bis(ethoxycarbonyl)-2,2′-bipyridine (146 mg, 0.487 mmol) and heated at 140° C. for another 12 hours. The solvent was removed under vacuum and the residue was dissolved in minimum amount of CH₂Cl₂, washed with de-ionized water for three times, and then dried over anhydrous Na₂SO₄. The solvent was evaporated on a rotary evaporator. The crude compound was purified by silica gel column chromatography (CH₂Cl₂: ACN=4:1).

Finally, the resulting solid was dissolved in a mixture of acetone (5 mL) and 1M sodium hydroxide (5 mL). The solution was heated to 100° C. under N2 for 24 h. After completing the hydrolysis, the solvent was removed again and solid was dissolved in basified H₂O solution (10 mL) and was titrated with 2 M HCl to pH 3 to afford a brown precipitate in 46% yield.

The spectral data of compound (m): MS (FAB, ¹⁰²Ru): m/z 801 (M+1)⁺. ¹H NMR (400 MHz, CD₃OD, 298 K): δ 9.02 (s, 1H), 9.00 (s, 2H), 8.99 (s, 1H), 8.00 (d, J=4.0 Hz, 1H), 7.94 (d, J=4.0 Hz, 1H), 7.87 (d, J=4.0 Hz, 2H), 7.82 (m, J=4.0 Hz, 4H), 7.75 (d, J=4.0 Hz, 1H), 7.70 (d, J=4.0 Hz, 1H), 7.47 (d, J=4.0 Hz, 1H), 7.24 (s, 1H), 7.10 (t, J=8.0 Hz, 1H).

### Example 3

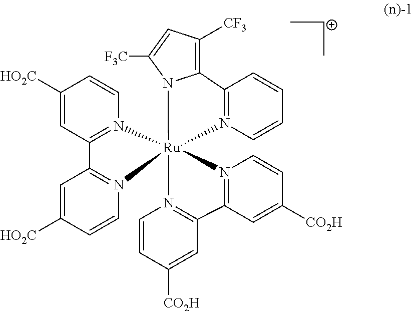

Compound (n)-1 was best prepared by direct treatment of dichloro-bis(4,4′-di(ethoxycarbonyl)-2,2′-bipyridine)ruthenium(II) (100 mg, 0.129 mmol) and 3,5-bis(trifluoromethyl)-2-(2′-pyridyl)pyrrole (42 mg, 0.15 mmol). Accordingly, these materials were dissolved in ethanol (20 mL) and the reaction mixture was heated to 100° C. under stirring for 14 h. After evaporating the solvent, the residue was extracted with dichloromethane, washed with deionized water three times (3×25 mL), and then dried over anhydrous Na₂SO₄. Evaporation of solvent then produced the crude product, which was then purified by silica gel column chromatography (CH₂Cl₂/MeOH=9:1). Finally, the resulting solid was dissolved in a mixture of acetone (5 mL) and 1M sodium hydroxide (5 mL). The solution was heated to 100° C. under N2 for 3 h. After completing the hydrolysis, the solvent was removed and solid was dissolved in basified H₂O solution (10 mL) and was titrated with 0.1 N HNO₃ to pH 3 to afford a brown precipitate. This brown product was then taken into a minimum amount of methanol and purified on Sephadex LH-20 column using methanol as the eluent. The main band was collected and solvent was evaporated to dryness. Compound (n)-1 was isolated in 54% yield.

The spectral data of compound of (n)-1: ¹H NMR (400 MHz, d₆-DMSO, 298 K): δ 9.14 (s, 2H), 9.07 (s, 1H), 9.02 (s, 1H), 7.96 (s, broad, 3H), 7.87 (s, broad, 1H), 7.81 (s, broad, 2H), 7.68 (s, broad, 1H), 7.57 (s, broad, 3H), 7.32 (s, broad, 1H), 7.08 (s, broad, 1H), 6.88 (s, 1H). ¹⁹F NMR (400 MHz, d₆-DMSO, 298 K): δ-53.78 (s, 3F), −58.35 (s, 3F).

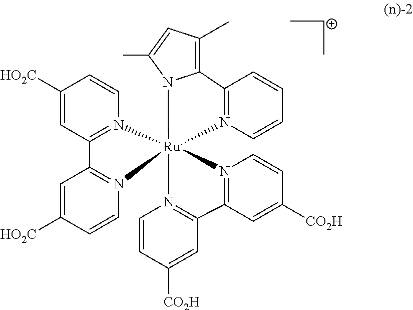

Compound (n)-2 was best prepared by direct treatment of dichloro-bis(4,4′-di(ethoxycarbonyl)-2,2′-bipyridine)ruthenium(II) (100 mg, 0.129 mmol) and 3,5-dimethyl-2-(2′-pyridyl)pyrrole (22 mg, 0.129 mmol). Accordingly, these materials were dissolved in ethanol (20 mL) and the reaction mixture was heated to 100° C. under stirring for 12 h. After evaporating the solvent, the residue was extracted with dichloromethane, washed with deionized water three times (3×25 mL), and then dried over anhydrous Na₂SO₄. Evaporation of solvent produced an oily residue, which was purified by silica gel column chromatography (CH₂Cl₂/MeOH=15:1). Finally, the solid was dissolved in a mixture of acetone (5 mL) and 1M sodium hydroxide (5 mL). The solution was heated to 100° C. under N₂ for 3 h. After completing the hydrolysis, the solvent was removed again and solid was dissolved in basic H₂O solution (10 mL) and was titrated with 0.1 N HNO₃ to pH 3 to afford a brown precipitate. This brown product was then taken into a minimum amount of methanol and purified on Sephadex LH-20 column using methanol as the eluent. The main band was collected and solvent was evaporated to dryness. Compound (n)-2 was isolated in 46% yield.

The spectral data of compound of (n)-2: ¹H NMR (400 MHz, d₆-DMSO, 298 K): δ 8.99 (s, 1H), 8.95 (s, 2H), 8.94 (s, 1H), 8.07 (d, J=5.6 Hz, 1H), 7.80 (m, broad, 5H), 7.65 (dd, J=4.4 Hz, 1.2 Hz, 2H), 7.48 (m, broad, 2H), 7.57 (d, J=5.6 Hz, 1H), 7.32 (s, broad, 1H), 6.51 (td, J=4 Hz, 2 Hz, 1H), 2.03 (s, 3H), 1.27 (s, 3H).

### DSSC Performance

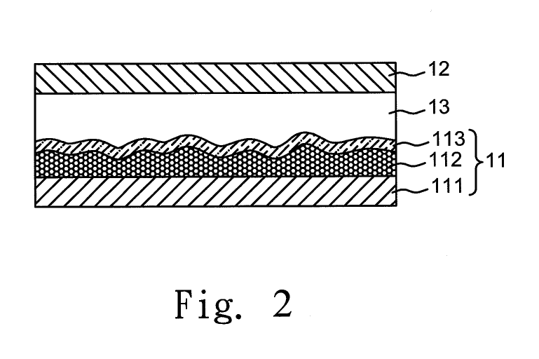

Referring to FIG. 2, a DSSC of an embodiment of the present invention comprises a first electrode 11 (photoanode), a second electrode 12 (cathode) and an electrolyte 13. The first electrode 11 comprises a transparent conductive substrate 111 and a porous membrane 112. The porous membrane 112, disposed on a surface of the transparent conductive substrate 111, is loaded with the aforementioned photosensitizers 113. The porous membrane 112 comprises a semiconductor material, such as TiO₂. In one embodiment, the transparent conductive substrate 111 comprises F-doped SnO₂ glass (FTO glass). The electrolyte 13 is disposed between the porous membrane 112 and the second electrode 12. The structures of the photosensitizers 113 are identical with the aforementioned photosensitizers; therefore, the detail description is omitted herein.

The aforementioned photosensitizers TFRS-1˜TFRS-3 are utilized to produce a DSSC of the present invention. The properties of DSSCs are illustrated in table 1, wherein the first electrode 11 comprises photosensitizers TFRS-1˜TFRS-3, a porous membrane TiO₂ and FTO glass; the second electrode 12 comprises a Pt electrode, such as a general glass doped with metal Pt and other conductive material, e.g. carbon black or graphite; the electrolyte comprises a mixture consisting of 0.6 M butylmethylimidazolium iodide (BMII), 0.03 M I₂, 0.10 M guanidinium thiocycanate, and 0.50 M tert-butylpyridine in 85% vol. acetonitrile and 15% vol. valeronitrile

TABLE 1

| | λ_{abs} (nm, | | J_{SC} | FF | |
|---|---|---|---|---|---|
| Dye | M⁻¹cm⁻¹) | Voc (mV) | (mA/cm²) | (%) | η (%) |
| TFRS-1 | 406 (13800) | 830 | 15.95 | 69.3 | 9.18 |
| | 532 (7900) | | | | |
| TFRS-2 | 424 (23400) | 820 | 17.15 | 67.8 | 9.54 |
| | 460 (21900) | | | | |
| | 533 (16400) | | | | |
| TFRS-3 | 374 (45000) | 810 | 17.38 | 63.5 | 8.94 |
| | 439 (25800) | | | | |
| | 503 (29200) | | | | |
| N719 | 396 (13600) | 760 | 15.64 | 72.0 | 8.56 |
| | 532 (14200) | | | | |

The DSSCs of the present invention have better photoelectric conversion efficiency as illustrated in Table 1. To be specific, the DSSCs of the present invention including photosensitizers TFRS-1˜TFRS-3 respectively have better η of 9.18%, 9.54% and 8.94% than that of N719 (n=8.56%). In addition, TFRS-1˜TFRS-3 are more efficient than N719, which are confirmed by the better performance data such as higher efficiencies, including better V_{OC}, J_{SC} and FF characteristics. In other words, the DSSCs of the present invention may include the first electrode prepared with the much thinner nanoporous TiO₂ layer so as to prevent the unnecessary reduction of V_{OC}. It has been reported that the V_{OC} is inverse proportional to the back recombination of injected electrons with the oxidized dye molecule or components in electrolyte. Moreover, usage of less amount of photosensitizers can also reduce the overall cost of DSSC fabrication.

To sum up, the photosensitizers of the present invention, including with at least one chelating azolate chelate, are thiocyanate-free and have better photoelectric conversion efficiency η and longer life expectancy for devices fabricated employing traditional N719 dye. Therefore, the DSSCs prepared with the photo sensitizers of the present invention may provide better performance in overall battery lifespan and efficiency.

While the invention can be subject to various modifications and alternative forms, a specific example thereof has been shown in the drawings and is herein described in detail. It should be understood, however, that the invention is not intended to be limited to the particular form disclosed, but on the contrary, the invention is intended to cover all modifications, equivalents, and alternatives falling within the spirit and scope of the appended claims.

What is claimed is:

1. A photosensitizer, comprising a chemical formula represented by formula (a):
RuL₁L₂L₃ (a)
wherein Ru is ruthenium;
L₁, L₂ and L₃ represent heterocyclic bidentate ligands;
L₁ has a chemical formula represented by formula (b);
L₂ has a chemical formula represented by formulae (b), (c), (d) or (e); and
L₃ has a chemical formula represented by formulae (c), (d) or (e), 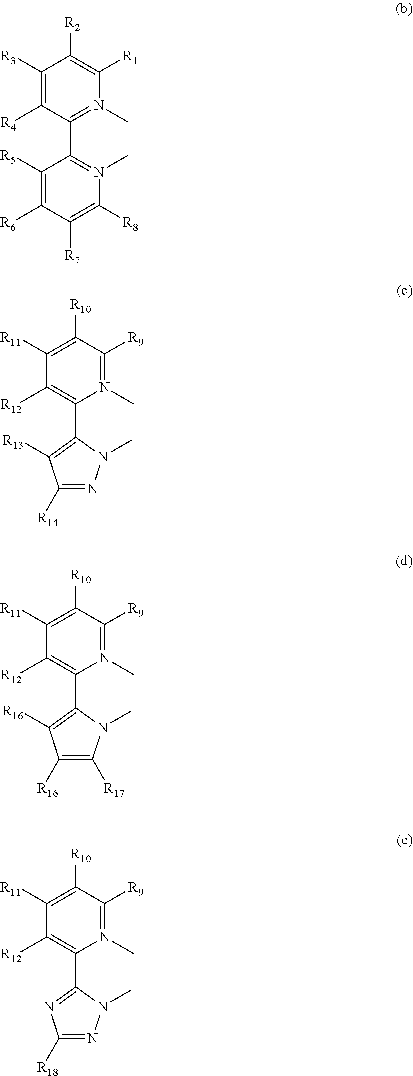
wherein each of R1 to R18 is a member independently selected from the group consisted of hydrogen, halogen, aryl group, alkenyl group, C1-C20 alkyl group, cycloalkyl group, alkynyl group, CN, CF₃, alkylamino, amino, alkoxy, heteroaryl, halogen substituted aryl group, haloalkyl substituted aryl group, haloalkyl substituted aromatic group and aryl substituted C1-C20 alkyl group.

2. The photosensitizer as claimed in claim 1, wherein each of R14, R15, R17 and R18 is independently CF₃.

3. The photosensitizer as claimed in claim 1, wherein each of R11, R13 and R16 is a member independently selected from the group consisted of aryl group, heteroaryl group, halogen substituted aryl group, haloalkyl substituted aryl group, haloalkyl substituted aromatic group and aryl substituted C1-C20 alkyl group.

4. The photosensitizer as claimed in claim 3, wherein each of R11, R13 and R16 is a member independently selected from the group consisted of hydrogen and following substituents, wherein R′ is C1-C20 alkyl group or C1-C20 cycloalkyl group.

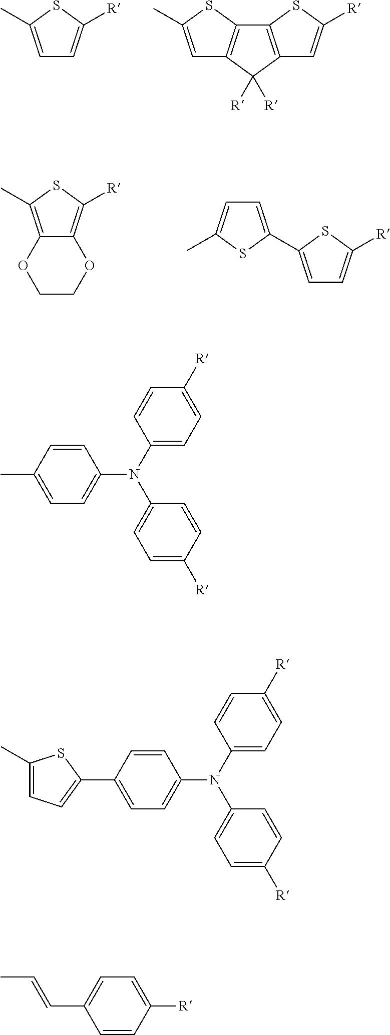

5. The photosensitizer as claimed in claim 1, wherein each of R3 and R6 is independently selected from the group consisted of carboxyl group and carboxyvinyl group.

6. A dye-sensitized solar cell comprising:
a first electrode comprising:
a transparent conductive substrate; and
a porous membrane comprising a semiconductor material, disposed on a surface of said transparent conductive substrate, and loaded with photosensitizers;
a second electrode; and
an electrolyte, disposed between said porous membrane and said second electrode, wherein said photosensitizers comprising a chemical formula represented by formula (a):
RuL₁L₂L₃ (a)
wherein Ru is ruthenium;
L₁, L₂ and L₃ represent heterocyclic bidentate ligands;
L₁ has a chemical formula represented by formula of (b);
L₂ has a chemical formula represented by formula (b), (c), (d) or (e); and
L₃ has a chemical formula represented by formula (c), (d) or (e); 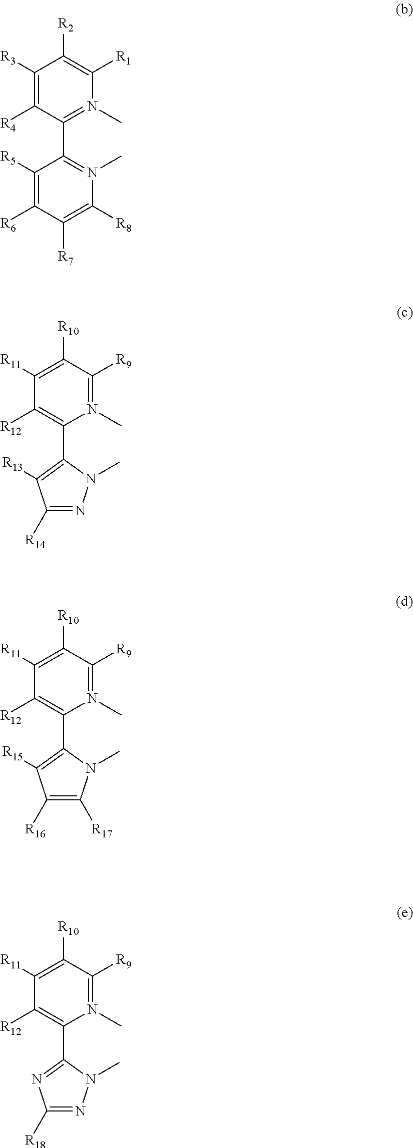
wherein each of R1 to R18 is a member independently selected from the group consisted of hydrogen, halogen, aryl group, alkenyl group, C1-C20 alkyl group, cycloalkyl group, alkynyl group, CN, CF₃, alkylamino, amino, alkoxy, heteroaryl, halogen substituted aryl group, haloalkyl substituted aryl group, haloalkyl substituted aromatic group and aryl substituted C1-C20 alkyl group.

7. The dye-sensitized solar cell as claimed in claim 6, wherein each of R14, R15, R17 and R18 is independently CF₃.

8. The dye-sensitized solar cell as claimed in claim 6, wherein each of R11, R13 and R16 is a member independently selected from the group consisted of aryl group, heteroaryl group, halogen substituted aryl group, halogen substituted aromatic group, haloalkyl substituted aryl group, haloalkyl substituted aromatic group and aryl substituted C1-C20 alkyl group.

9. The dye-sensitized solar cell as claimed in claim 8, wherein each of R11, R13 and R16 is a member independently selected from the group consisted of hydrogen and following substituents, wherein R′ is C1-C20 alkyl group or C1-C20 cycloalkyl group.

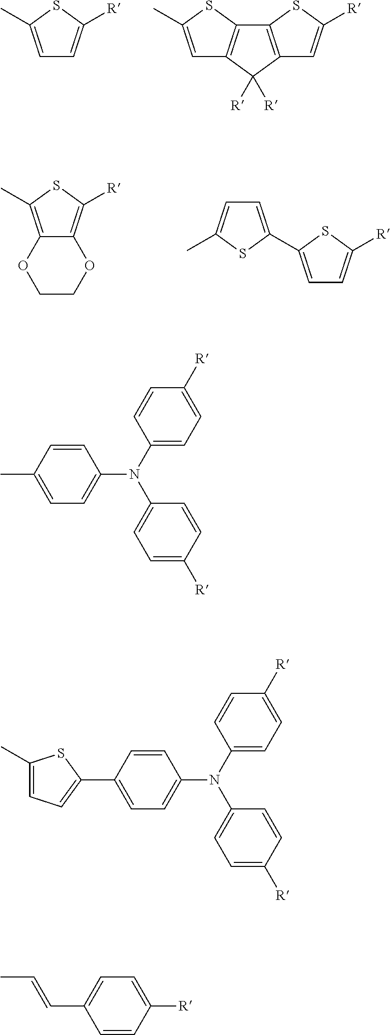

10. The dye-sensitized solar cell as claimed in claim 6, wherein each of R3 and R6 is independently from the group consisted of carboxyl group and carboxyvinyl group.

11. The dye-sensitized solar cell as claimed in claim 6, wherein the material of said semiconductor comprises TiO₂.

12. The dye-sensitized solar cell as claimed in claim 6, wherein said transparent conductive substrate comprises FTO glass.
